(19) United States
(12) Patent Application Publication
(10) Pub. No.: US 2008/0157247 A1
(43) Pub. Date: Jul. 3, 2008

(54) Image sensor and method for manufacturing the same

(75) Inventor: Young Je Yun, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/001,640

(22) Filed: Dec. 11, 2007

(30) Foreign Application Priority Data
Dec. 27, 2006 (KR) 10-2006-0135634

(51) Int. Cl. H01L 31/0232; H01L 21/04

(52) U.S. Cl. 257/432; 438/70; 257/E31.127; 257/E21.04

(57) ABSTRACT

An image sensor and a method for manufacturing the same are provided. The image sensor includes a photodiode region, an insulation layer structure, a light leakage preventing unit, color filters, and microlenses. The photodiode region in a pixel area of a semiconductor substrate generates an electric signal corresponding to entered light. The photodiode region includes a first photodiode, a second photodiode, and a third photodiode. The insulation layer structure includes trenches corresponding to boundaries between the first to third photodiodes. The light leakage preventing unit is formed in the trenches between the photodiodes and prevents light from passing through the trenches. The color filters are formed on the insulation layer structure corresponding to the first to third photodiodes, and the microlenses are disposed on the color filter corresponding to each of the color filters.

### CROSS-REFERENCE TO RELATED APPLICATIONS

The present application claims priority under 35 U.S.C. 119 and 35 U.S.C. 365 to Korean Patent Application No. 10-2006-0135634 (filed on Dec. 27, 2006), which is hereby incorporated by reference in its entirety.

### BACKGROUND

In general, an image sensor is a semiconductor device that transforms optical images to electric signals. A charge coupled device (CCD) and a complementary metal-oxide semiconductor (CMOS) image sensor are representative image sensors according to the related art.

Image sensor manufacturing methods, according to the related art, form gaps between microlenses of the image sensor. Light focused on a particular microlens can leak through an area corresponding to a gap between the microlens and an adjacent microlens, and enter into an adjacent photodiode. The leaked light causes optical cross-talk and color mixing, thereby degrading color purity. As a result, the image quality of a photodiode is deteriorated.

### SUMMARY

Embodiments of the present invention provide an image sensor for improving an image quality of a photodiode by preventing light that strikes microlenses from leaking into gaps between the microlenses, and a method for manufacturing the same.

In one embodiment, an image sensor includes: a photodiode region in a pixel area of a semiconductor substrate for generating an electric signal corresponding to incident light; a photodiode region having a first photodiode, a second photodiode, and a third photodiode; an insulation layer structure having trenches corresponding to boundaries of the first to third photodiodes; a light leakage preventing unit for preventing light from passing the trenches by filling up the trenches; color filters on the insulation layer structure corresponding to the first to third photodiodes; and microlenses on the color filter corresponding to each of the color filters.

In another embodiment, a method for manufacturing an image sensor includes: forming a photodiode region in a pixel area of a semiconductor substrate for generating an electric signal corresponding to incident light, including a first photodiode, a second photodiode, and a third photodiode; forming an insulation layer structure by forming an insulation layer on the first to third photodiodes to cover the first to third photodiodes, coating a photoresist film on the insulation layer, and forming trenches at boundaries of the first to third photodiodes through patterning the insulation layer using the photoresist film; forming a light leakage preventing unit in the trenches by depositing a gap fill material on the insulation layer structure; forming color filters on the insulation layer structure corresponding to the first to third photodiodes; and forming microlenses on the color filter corresponding to each of the color filters.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to an embodiment.

FIG. 2 is a top view of a photodiode region shown in FIG. 1.

FIG. 3A and FIG. 3B are cross-sectional views illustrating a method of forming an insulation layer structure on a photodiode region.

FIG. 4 is a cross-sectional view illustrating a method of forming a light leakage preventing unit on the insulation layer structure.

FIG. 5 is a cross-sectional view illustrating a method of forming a color filter structure on the insulation layer structure.

FIG. 6 is a cross-sectional view illustrating a method of forming a planarization layer on the color filter.

FIG. 7 is a cross-sectional view for illustrating a method of forming microlenses over the planarization layer.

### DETAILED DESCRIPTION OF THE EMBODIMENTS

Hereinafter, an image sensor and a method for manufacturing the same according to embodiments of the present invention will be described in detail with reference to the accompanying drawings.

In the description of embodiments, it will be understood that when a layer (or film) is referred to as being “on” another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

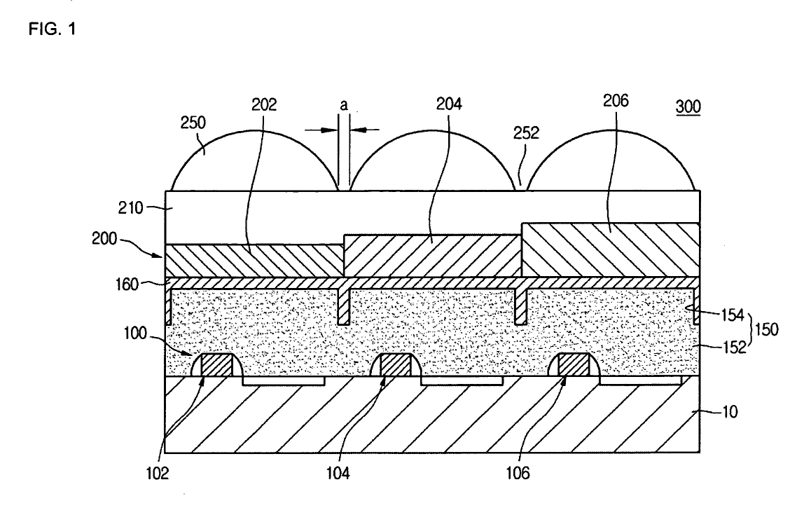

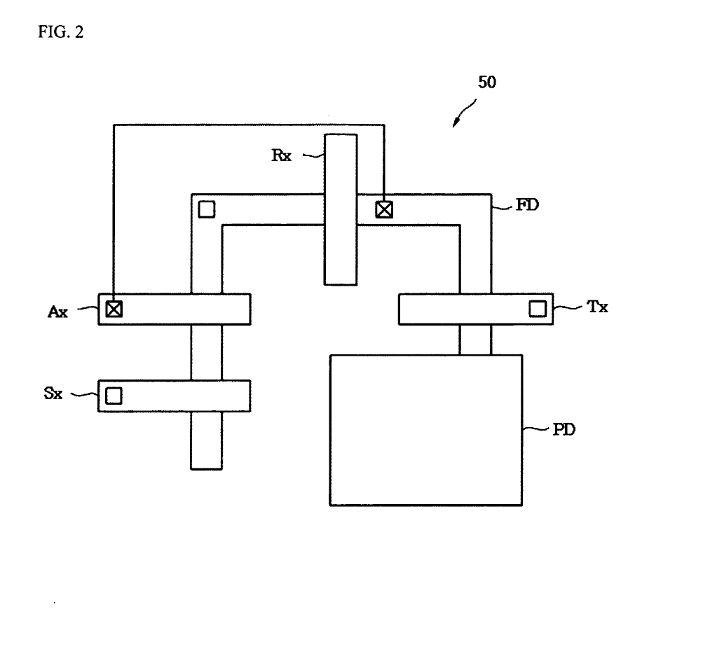

FIG. 1 is a cross-sectional view of an image sensor according to one embodiment, and FIG. 2 is a top view of a photodiode region shown in FIG. 1. An image sensor 300 according to the embodiment may include a photodiode region 100, an insulation layer structure 150, an light leakage preventing unit 160, color filters 200, a planarization layer 210, and microlenses 250.

The photodiode region 100 is formed in a pixel area of a semiconductor substrate 10 and generates an electric signal corresponding to entering light. The photodiode region 100 includes a first photodiode 102, a second photodiode 104, and a third photodiode 106.

Referring to FIG. 2, each of the first to third photodiodes 102, 104, and 106 includes a photodiode PD for sensing an amount of light, a transfer transistor Tx, a reset transistor Rx, a select transistor Sx, and an access transistor Ax. A drain of the transfer transistor operates as a floating diffusion layer FD.

Referring to FIG. 1 again, the insulation layer structure 150 includes an insulation layer 152 for insulating a line (not shown) having a multiple layer structure covering the semiconductor substrate 10, which has three photodiodes 102, 104, and 106 formed thereon. Trenches 154 are formed in a top surface of the insulation layer 152 in areas corresponding to boundaries between the first to third photodiodes 102, 104, and 106, at a predetermined width w and depth d.

In one embodiment, the insulation layer 152 may comprise a Nitride. For example, the insulation layer 152 may comprise SiN having a light refractive index of about 1.9 to 2.0. The thickness of the insulation layer 152 may be about 200˜300 nm. The insulation layer 152 may be formed by methods such as physical vapor deposition, chemical vapor deposition (CVD, e.g., Low Pressure CVD, High Density Plasma CVD, or Plasma Enhanced CVD), or blanket deposition.

The trenches 154 may be formed to have a depth less than the thickness of the insulation layer 152. Also, the trenches 154 are formed to have the width w identical to or slightly wider than the width a of gaps 252 formed between microlenses 250. Gaps 252 may be formed between the microlenses 250 during microlens fabrication. The size of the gaps 252 is at least about 200 nm to 300 nm. The width w of the trenches 154 may be about 100 nm to 400 nm or less, and the depth of the trench 154 may be about 100 nm to 300 nm.

The light leakage preventing unit 160 prevents light focused to the microlenses 250 from being leaked to an area of the gaps 252 formed between the microlenses while the focused light is transmitted to the photodiode PD. The light leakage preventing unit 160 may be formed in the trenches 154, and may substantially fill the trenches 154. The light leakage preventing layer may also be formed to cover the entire top surface of the insulation layer structure 150 to a predetermined thickness, thereby substantially planarizing the top surface of the image sensor 300.

The thickness of the portion of the light leakage preventing unit 160 covering the top surface of the insulation layer structure 150 (i.e., the thickness from the top of the light preventing unit 160 to the top surface of the insulation layer 152), is about 10 nm to 20 nm.

In one embodiment, the light leakage preventing unit 160 may comprise oxide material, such as tetra ethyl ortho silicate (TEOS) oxide material, having a refractive index lower than that of the insulation layer structure's material SiN. The light refractive index of the TEOS oxide material is about 1.4 to 1.5. The light leakage prevention unit 160 may be formed by methods such as physical vapor deposition, chemical vapor deposition (CVD, e.g., Low Pressure CVD, High Density Plasma CVD, or Plasma Enhanced CVD), or blanket deposition.

Color filters 200 may be formed on the light leakage preventing unit 160. The color filters 200 include a blue color filter 202 formed at a predetermined area corresponding to the first photodiode 102 for passing a blue visible light, a green color filter 204 formed at a predetermined area corresponding to the second photodiode 104 for passing a green visible light, and a red color filter 206 formed at a predetermined area corresponding to the third photodiode 106 for passing a red visible light.

The blue, green, and red color filters 202, 204, and 206 may be formed to have different thicknesses, as shown in FIG. 1. More specifically, the color filters are formed to have different thicknesses over a substantially flat substrate. For example, a red color filter 206 may have a greater thickness than a green color filter 204 adjacent thereto, and the green color filter 204 may have a greater thickness than a blue color filter 202 adjacent thereto and on an opposite side of the green filter 204 from the red color filter 206. Alternatively, the blue, green, and red color filters 202, 204, and 206 may be formed to have the same thickness.

The planarization layer 210 may be formed over or on the color filter 200. The planarization layer 210 reduces or substantially eliminates step differences that may be formed between the blue, green, and red color filters 202, 204, and 206 (e.g., differences in thickness where the color filters meet).

The microlenses 250 accurately focus and transmit light to each of the photodiode regions 100. The microlenses 250 are formed to be individually aligned with the blue, green, or red color filters 202, 204, and 206 on the planarization layer 210.

More specifically, a photoresist film is formed over the planarization layer 210. The photoresist film may be formed of a conventional polymer photoresist material deposited by conventional methods (e.g., spin-coating). The photoresist layer may be formed to have a thickness of 200-500 nm. The photoresist film is then patterned through an exposure and development process, including a thermal reflow process at a temperature of about 120° C. to 250° C. The thermal reflow process causes the microlenses to have a convex or hemispheric shape.

Gaps 252 may be formed between the microlenses 250 during a microlenses forming process. The size of the gaps 252 is at least about 100 nm to 300 nm.

Referring to FIGS. 1 and 2, although the microlenses 250 accurately focus light and transmit the focused light to each of the photodiodes PD, a portion of the focused light is leaked to an area corresponding to a gap 252. In a related art device, while the focused light is transmitted to the photodiode PD through the insulation layer structure 150 and after the focused light passes each of the color filters 200, leaked light may mix with another light passing through an adjacent color filter. This results in optical cross-talk between adjacent photodiodes PD. Consequently, the image quality of the photodiode PD becomes degraded.

In the embodiments of the present invention, the trenches 154 are formed in the insulation layer structure 150 corresponding to the gaps 252 between the microlenses 250. A light leakage preventing unit 160 may be formed by filling the trenches 154 with predetermined material having a light refractive index lower than that of the insulation layer structure 150. The light leakage preventing unit 160 decreases optical cross-talk by reflecting substantially all light reaching the insulation layer structure 150 that might otherwise leak to another photodiode after the light passes through the color filters 200.

In more detail, when the light reaches to the insulation layer structure 150 after the light has been accurately focused by one of the microlenses 250, it passes to the corresponding color filter. Most of the filtered light passes accurately from the color filter to its corresponding photodiode PD. However, a part of the filtered light propagates toward the light leakage preventing unit 160. The physical properties of light prevent it from passing from a material having a higher light reflective index to a material having a lower light reflective index. Thus, the light leakage preventing unit 160 reflects substantially all of the leaked light to the photodiode PD because the light leakage preventing unit 160 has a lower light refractive index (about 1.4 to about 1.5) than that of the insulation layer structure 150 (about 1.9 to about 2.0).

Consequently, the image quality of the photodiode PD is improved because the colors are not mixed and the optical cross talk between adjacent photodiodes is prevented. The display quality of the image sensor 200 can be thereby improved.

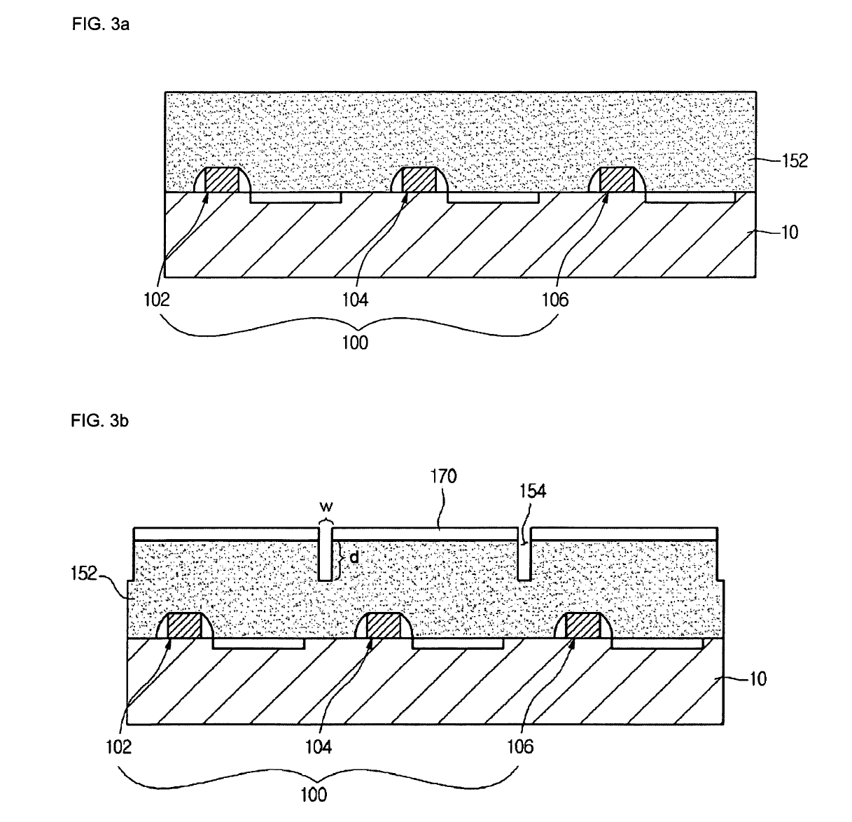

FIG. 3A to FIG. 7 are cross-sectional views for illustrating a method for fabricating an image sensor according to embodiments of the present invention.

FIG. 3A and FIG. 3B are cross-sectional views illustrating forming an insulation layer structure on a photodiode region, as shown in FIG. 1. In order to manufacture an image sensor 300, a photodiode region 100 having first to third photodiodes 102, 104, and 106 is formed on a semiconductor substrate 10. Although the photodiode region 100 includes three photodiodes 102, 104, and 106 in one embodiment, more photodiodes 100 can be disposed on the semiconductor substrate 10 as needed to achieve a desired resolution.

Referring to FIG. 2, each of the first, the second, and the third photodiodes 102, 104, and 106 includes a photodiode PD for sensing an amount of light, a transfer transistor Tx, a reset transistor Rx, a select transistor Sx, and an access transistor Ax. A drain of the transfer transistor operates as a floating diffusion layer FD.

After the photodiode region 100 is formed on the semiconductor substrate 10, an insulation layer 152 is formed on the semiconductor substrate 10 to cover the first to third photodiodes 102, 104, and 106. The insulation layer 152 may comprise SiN having a light refractive index of about 1.9 to about 2.0.

Then, a photoresist pattern 170 defining trenches that correspond to boundaries between the first to third photodiodes 102, 104, and 106 is formed by depositing a photoresist film on the insulation layer 152 and patterning the photoresist film through a lithography process, as shown in FIG. 3B. The photoresist film may be formed of a conventional polymer photoresist material deposited by conventional methods (e.g., spin-coating). The photoresist film is then patterned through a conventional exposure and development process (e.g., photolithography by selective irradiation through a mask and subsequent development).

Then, the insulation layer 152 is etched using the photoresist pattern 170 as an etching mask, thereby forming trenches 154 in insulation layer structure 150 aligned with boundaries between the first to third photodiodes 102, 104, and 106. The insulation layer 152 is etched using a reactive ion etching method for forming the trenches 154.

The trenches 154 are formed to have a depth less than the thickness of the insulation layer 152. Also, the trenches 154 are formed to have a width w identical to or slightly wider than the size a of the gaps 252 formed between the microlenses 250. For example, the width of the trench 154 is about 100 nm to 400 nm, and the depth d of the trench 154 is about 100 nm to 300 nm.

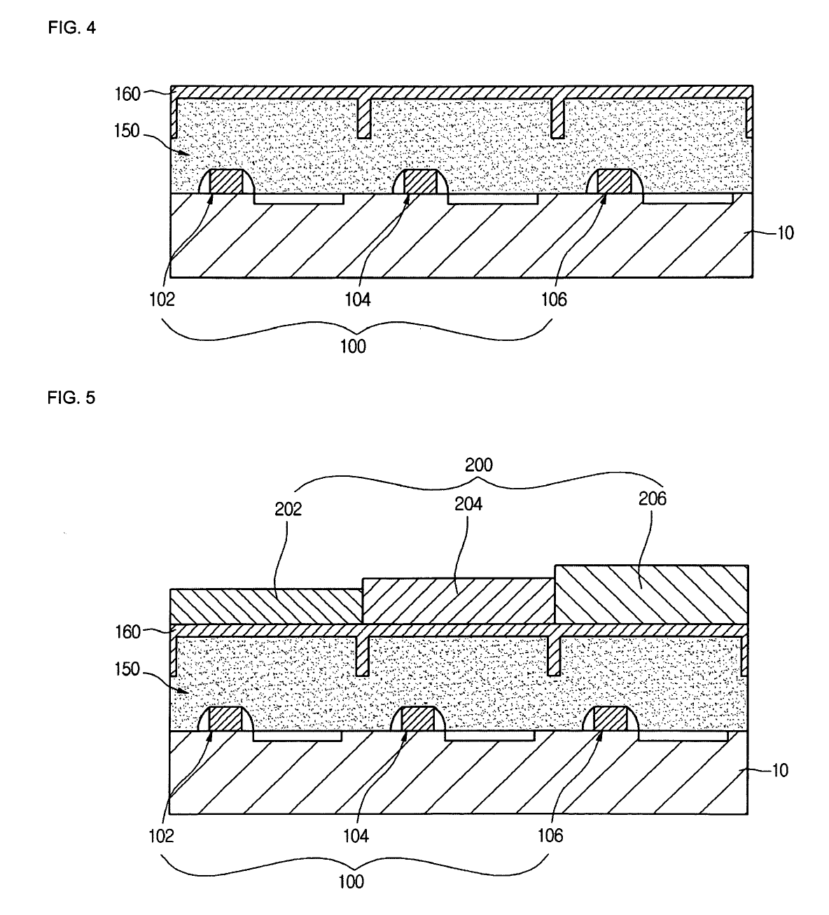

FIG. 4 is a cross-sectional view illustrating a light leakage preventing unit on an insulation layer structure 150. After the trenches 154 are formed corresponding to boundaries between the first to third photodiodes 102, 104, and 106, a light leakage preventing unit 160 may be formed by depositing oxide material on the insulation layer structure 150, including the trenches 154.

Although forming the light leakage preventing unit 160 may include completely filling the trenches 154, large step differences may be formed in the upper surface of the light leakage preventing unit 160 at the trenches 154. In order to minimize the step differences, a deposition process is continuously performed until oxide material is further deposited on the insulation layer structure 150 to a thickness of about 10 nm to 20 nm after the trenches 154 are completely filled with the oxide material. To planarize the upper surface of the image sensor 300, a planarization layer may be formed over the light leakage preventing unit 160.

The oxide material may comprise, for example, TEOS oxide material, having a refractive index lower than that of SiN, which may be comprised in the insulation layer structure 150. The light refractive index of the TEOS oxide material is about 1.4 to about 1.5.

FIG. 5 is a cross-sectional view illustrating a color filter structure on the insulation layer structure shown in FIG. 4. Color filters 200 are formed over or on the oxide layer 160 to be aligned with the first to third photodiodes 102, 104, and 106. In one embodiment, the color filters 200 include a blue color filter 202, a green color filter 204, and a red color filter 206.

The blue, green, and red color filters 202, 204, and 206 are formed by coating photosensitive substances each having pigment and/or dyes corresponding to the color of one of the color filters, and patterning the coated photosensitive substances through a photo-etching method.

In one embodiment, the thicknesses of the blue, green, and red color filters 202, 204, and 206 may be different as shown in FIG. 5. Alternatively, the thicknesses of the blue, green, and red color filters 202, 204, and 206 may be the same.

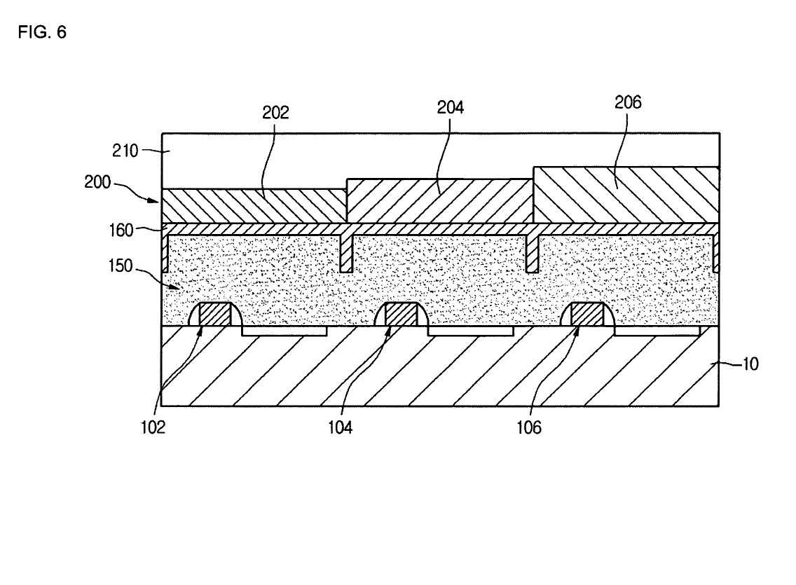

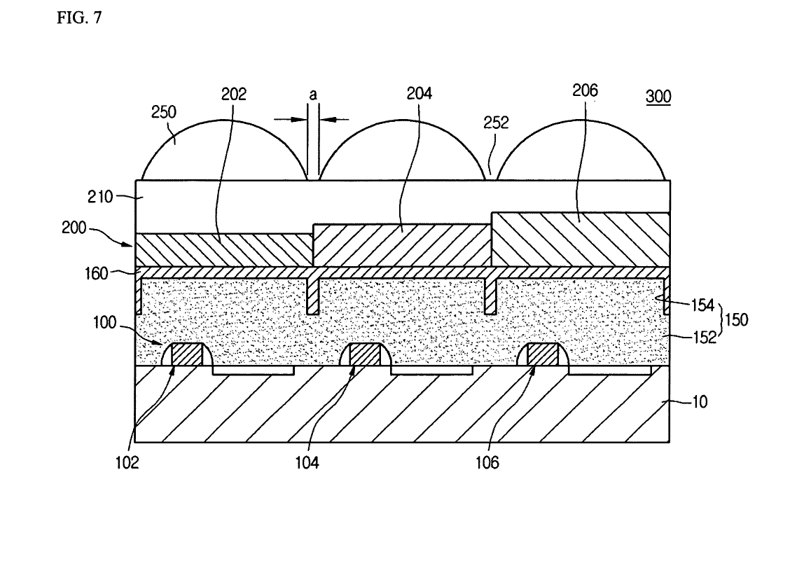

FIG. 6 is a cross-sectional view illustrating forming a planarization layer on a color filters 200 shown in FIG. 5. A planarization layer 210 is formed over or on the color filter 200 to completely cover the color filters 200. The planarization layer 210 reduces or completely eliminates step differences between the blue, green, and red color filters 202, 204, and 206, each having different thicknesses.

Referring to FIG. 7, a photoresist film is formed over or on the planarization layer 210, and the photoresist film is patterned by a lithography process. The photoresist film may be formed of a conventional polymer photoresist material deposited by conventional methods (e.g., spin-coating). The photoresist film is then patterned through a conventional exposure and development process (e.g., photolithography by selective irradiation through a mask and subsequent development).

Then, microlenses 250 are formed in a convex or hemispheric shape. This may be achieved by performing a reflow process for heating the pattern photoresist film at a temperature that melts the photoresist film (about 150° C. to 250° C.). The individual microlenses are formed to be aligned with the blue, green, and red color filters 202, 204, and 206.

Undesired gaps 252 having a width a of at least about 200 nm to 300 nm may be formed between the individual microlenses 250 when the microlenses 250 are formed. Light striking microlenses 250 may leak through the gaps 252, causing color mixing and optical cross talk between adjacent photodiodes PD. In order to prevent the color mixing and the optical cross talk, the light leakage preventing unit 160, as described above, reflects substantially all of the light reaching the insulation layer structure 150 after the light passes the colors filter 200. The light is accurately reflected into the appropriate photodiodes PD, thereby preventing the color mixing and the optical cross talk.

As described above, in one embodiment, the light leakage preventing unit is formed at boundaries of photodiodes in the insulation layer structure. Since the light leakage preventing unit reflects substantially all of the light focused to each of the photodiodes, the image quality of the photodiode and the display quality of the image sensor can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a photodiode region in a pixel area of a semiconductor substrate for generating an electric signal corresponding to entered light, including a first photodiode, a second photodiode, and a third photodiode;
an insulation layer structure having trenches corresponding to boundaries between two or more of the first, second, and third photodiodes;
a light leakage preventing unit in the trenches for preventing light from passing through the trenches;
color filters over the insulation layer structure corresponding to the first, second, and third photodiodes; and
microlenses over the color filters corresponding to each of the color filters.

2. The image sensor according to claim 1, wherein the insulation layer structure comprises a nitride layer.

3. The image sensor according to claim 1, wherein a width of the trenches is about 100 nm˜400 nm, and a depth of the trench is less than a thickness of the insulation layer structure.

4. The image sensor according to claim 3, wherein the depth of the trench is about 100˜300 nm.

5. The image sensor according to claim 1, wherein the light leakage preventing unit comprises an oxide material having a light refractive index lower than that of the insulation layer structure.

6. The image sensor according to claim 5, wherein the oxide material comprises TEOS (tetra ethyl ortho silicate).

7. The image sensor according to claim 1, wherein the light leakage preventing unit is over the entire top surface of the insulation layer structure, including the trenches to a thickness of about 10 nm to 20 nm.

8. A method for manufacturing an image sensor, the method comprising:
forming a photodiode region in a pixel area of a semiconductor substrate for converting light to an electric signal, including a first photodiode, a second photodiode, and a third photodiode;
forming an insulation layer structure by forming an insulation layer on the first, second, and third photodiodes to cover the first, second, and third photodiodes, coating and patterning a photoresist film on the insulation layer to define trenches at boundaries between the first, second, and third photodiodes, and forming the trenches by etching the insulation layer using the patterned photoresist film as a mask;
forming a light leakage preventing unit in the trenches by depositing a gap fill material over the insulation layer structure;
forming color filters over the insulation layer structure corresponding to the first, second, and third photodiodes; and
forming microlenses over the color filters corresponding to each of the color filters.

9. The method according to claim 8, wherein the insulation layer structure comprises a nitride layer.

10. The method according to claim 8, wherein a width of the trench is about 100 nm˜400 nm, and a depth of the trench is less than a thickness of the insulation layer structure.

11. The image sensor according to claim 10, wherein the depth of the trench is about 100 nm˜300 nm.

12. The method according to claim 8, wherein the light leakage preventing unit is formed over an entire top surface of the insulation layer structure to a thickness of about 10 nm to 20 nm.

13. The method according to claim 8, wherein the light leakage preventing unit comprises oxide material having a light refractive index lower than that of the insulation layer structure.

14. The method according to claim 13, wherein the oxide material comprises TEOS (tetra ethyl ortho silicate).

15. The method according to claim 13, further comprising forming a planarization layer over the color filters prior to forming the microlenses.

16. The method according to claim 8, wherein gaps are formed between the microlenses during the microlens forming step.

17. The method according to claim 16, wherein the gaps have a width of about 100 nm to about 300 nm and are aligned with the boundaries between the first, second, and third photodiodes.

18. The image sensor according to claim 1, further comprising gaps between the microlenses.

19. The image sensor according to claim 18, wherein the gaps have a width of about 100 nm to about 300 nm, and are aligned with the boundaries between the first, second, and third photodiodes.

20. The image sensor according to claim 1, further comprising a planarization layer over the color filters.
